(19) United States
(12) Patent Application Publication
(10) Pub. No.: US 2026/0142257 A1
(43) Pub. Date: May 21, 2026

(54) CHARGING METHOD AND CHARGING DEVICE FOR BATTERY

(71) Applicant: ENPOWER (PEKING) INC., Beijing (CN)

(72) Inventors: Chen WANG, Beijing (CN); Meng YAO, Beijing (CN); Yong CHE, Beijing (CN)

(21) Appl. No.: 19/446,980

(22) Filed: Jan. 13, 2026

Related U.S. Application Data
(63) Continuation of application No. PCT/CN2024/118890, filed on Sep. 13, 2024.

(30) Foreign Application Priority Data
Jul. 14, 2023 (CN) 202310871688.X

(51) Int. Cl. H01M 10/44; G01R 31/367; G01R 31/385

(52) U.S. Cl. CPC H01M 10/446; G01R 31/367; G01R 31/385

(57) ABSTRACT

The present invention provides a charging method and charging device for a battery. The charging method comprises the following steps: (1) on the basis of charging time T and a preset first mapping table, determining an average charging rate Cₐ, an initial charging rate C₁, and a termination charging rate C_{T}; on the basis of the preset number n of battery cycles, determining charging time t and a rate increase amplitude I of a signal charging rate; and (2) on the basis of the initial charging rate C₁, the termination charging rate C_{T}, and the charging time t and the rate increase amplitude I of the signal charging rate, determining a charging combination scheme.

### CROSS-REFERENCE TO RELATED APPLICATIONS

This application is a continuation of International Patent Application No. PCT/CN2024/118890 filed on Sep. 13, 2024, which claims priority to Chinese patent application No. 202310871688.X, titled “CHARGING METHOD AND CHARGING DEVICE FOR BATTERY”, and filed with China National Intellectual Property Administration on Jul. 14, 2023, the entire contents of which are incorporated herein by reference.

### FIELD

The present disclosure relates to the field of battery charging technologies, and relates to a charging method and a charging device for a battery.

### BACKGROUND

A metal lithium, when used as an anode in combination with a high-energy-density cathode material, can significantly increase an energy density of lithium-ion secondary batteries. Lithium metal batteries possess a high energy density, but their cycling performance and cycling safety still lag considerably behind those of conventional lithium-ion batteries. This is primarily because, during charging and discharging of the lithium metal batteries, lithium ions undergo repeated deposition on and stripping from a surface of the metal lithium, which is likely to lead to formation of dead lithium and dendrites, drastically reducing a cycle life and safety of a cell. Currently, most lithium metal batteries achieve long-term cycling performance using low-rate charging methods through strategies such as anode surface protection and electrolyte modification. However, lithium metal batteries that possess both high-rate charging capability and long-term cycling performance have not yet been reported.

### SUMMARY

In view of an issue that a lithium metal battery cannot maintain satisfactory cycling performance under high-rate charging conditions, the present disclosure provides a charging method and a charging device for a battery. By analyzing a charging rate and cycling performance of the lithium metal battery, the present disclosure designs and selects a combined charging method, achieving the lithium metal battery that possesses both high-rate charging performance and satisfactory cycling performance.

To achieve the above objective, the present disclosure adopts the following technical solutions.

In a first aspect, the present disclosure provides a charging method for a battery. The charging method includes the following steps of: (1) determining an average charging rate Cₐ, an initial charging rate C₁, and a termination charging rate C_{T} based on a charging duration T and a predetermined first mapping table, and determining a charging duration t for a single charging rate and a rate increment I based on a predetermined battery cycle count n; and (2) determining a charging combination scheme based on the initial charging rate C₁, the termination charging rate C_{T}, the charging duration t for the single charging rate, and the rate increment I.

As a preferred solution of the present disclosure, in the step (1), the average charging rate Cₐ=1/T.

As a preferred solution of the present disclosure, the charging duration satisfies 0.2 h≤T≤5 h.

As a preferred solution of the present disclosure, the predetermined first mapping table in the step (1) is configured to record an empirical correspondence between the predetermined charging duration and the initial charging rate.

As a preferred solution of the present disclosure, the termination charging rate C_{T} in the step (1) is calculated based on a formula C_{T}=2Cₐ−C₁.

As a preferred solution of the present disclosure, in the step (1), the charging duration for the single charging rate satisfies

$$t = \frac{T}{2 n + β} ,$$

and the rate increment satisfies

$$I = \frac{{C}_{T} - {C}_{1}}{2 n + β} ,$$

where β represents a correction factor, 100≤β≤1000 and β is an integer, and β=0 during first charging.

As a preferred solution of the present disclosure, in the step (1), n≥100.

As a preferred solution of the present disclosure, the charging combination scheme in the step (2) includes a combination of (2n+β+1) charging rates, the single charging rate corresponding to the charging duration t.

As a preferred solution of the present disclosure, the charging combination scheme in the step (2) includes: charging at the initial charging rate C₁, and charging sequentially at remaining (2n+β) charging rates in an ascending order of magnitude of the remaining (2n+β) charging rates, where β represents a correction factor, 100≤β≤1000 and β is an integer, and β=0 during first charging.

As a preferred solution of the present disclosure, the charging combination scheme in the step (2) includes: charging at the initial charging rate C₁ for t hours when a state of charge (SOC) of the battery is 0%, switching to charge at a rate of C₁+k*I for t hours, repeating the switching sequentially until (2n+β) switches have been performed, and ending with charging at the termination charging rate C_{T} for t hours, where k represents a quantity of switches.

As a preferred solution of the present disclosure, during charging at the single charging rate in the step (2), charging cut-off voltage protection is set.

As a preferred solution of the present disclosure, a cut-off condition for the charging cut-off voltage protection is: ending a charging process at a current rate, and switching to charging at a next rate, when a charging voltage of the battery reaches 4.3V.

As a preferred solution of the present disclosure, the charging method further includes the following step of: (3) verifying the charging combination scheme, correcting the charging combination scheme when a correction of the charging combination scheme is required subsequent to the verifying the charging combination scheme, and continuing the verifying subsequent to the correcting, until the charging combination scheme meets an evaluation criterion.

As a preferred solution of the present disclosure, in the step (3), the verifying includes: performing a cycle test on the battery based on the charging combination scheme, measuring an actual cycle count nᵣ at which a capacity retention rate of the battery declines to 80%, and verifying the charging combination scheme based on a difference between the predetermined battery cycle count n and the actual cycle count nᵣ.

As a preferred solution of the present disclosure, when n−nᵣ≤25, the charging combination scheme meets a predetermined requirement.

As a preferred solution of the present disclosure, when 25<n−nᵣ≤50, a correction is required for each of the charging duration t for the single charging rate and the rate increment I.

As a preferred solution of the present disclosure, when 50<n−nᵣ, a correction is required for the initial charging rate C₁.

As a preferred solution of the present disclosure, when 25<n−nᵣ≤50, a correction factor β is introduced to correct the charging duration t for the single charging rate and the rate increment I, where

$$t = \frac{T}{2 n + β} ,$$

the rate increment satisfies

$$I = \frac{{C}_{T} - {C}_{1}}{2 n + β} ,$$

100≤β≤1000 and β is an integer, and a value of β increases as a quantity of corrections increases.

As a preferred solution of the present disclosure, when 50<n−nᵣ, a correction factor α is introduced to correct the initial charging rate C₁, the termination charging rate C_{T}, and the rate increment I, where 0.5≤α<1, and a new initial rate C₁₊ₘ=α*C₁, where m represents a quantity of corrections, and a value of a decreases as the quantity of corrections increases.

In a second aspect, the present disclosure provides a charging device. The charging device includes: a charging duration input module configured to allow for an input of a charging duration T that is predetermined; a charging rate obtaining module configured to determine an average charging rate Cₐ, an initial charging rate C₁, and a termination charging rate C_{T} based on the charging duration T and a predetermined first mapping table; a cycle count input module configured to allow for an input of a predetermined battery cycle count n; a single-charging-rate charging duration and rate increment obtaining module configured to determine a charging duration t for a single charging rate and a rate increment I based on the predetermined battery cycle count n, the charging duration T, the initial charging rate C₁, and the termination charging rate C_{T}; a charging combination scheme determination module configured to generate a charging combination scheme; and a charging module configured to charge a battery based on the charging combination scheme.

As a preferred solution of the present disclosure, the charging device further includes: a verification and determination module configured to verify a charging result, for determining whether a correction is required for the charging combination scheme; and a correction module configured to correct the charging combination scheme based on a verification and determination result.

As a preferred solution of the present disclosure, the correction module includes: a correction factor α input module configured to allow for an input of a value of α; an initial charging rate C₁, termination charging rate C_{T}, and rate increment I correction module configured to correct the initial charging rate C₁, the termination charging rate C_{T}, and the rate increment I based on the input correction factor α; a correction factor β input module configured to allow for an input of a value of β; a single-charging-rate charging duration t and rate increment I correction module configured to correct the charging duration t for the single charging rate and the rate increment I based on the input correction factor β; and an output module configured to output the corrected charging combination scheme that meets predetermined performance.

Compared with the related art, the present disclosure has the following advantageous effects.

By analyzing the charging rate and the cycling performance of the lithium metal battery, the present disclosure designs and selects the combined charging method, which enables charging the lithium metal battery at a rate of 0.2 C or higher while ensuring the cycling performance of the lithium metal battery.

### BRIEF DESCRIPTION OF THE DRAWINGS

FIG. 1 is a flowchart illustrating an example of a charging method according to an embodiment of the present disclosure.

FIG. 2 is a flowchart illustrating an example of a charging method according to an embodiment of the present disclosure.

FIG. 3 is a schematic diagram showing an example of a charging device according to an embodiment of the present disclosure.

### DETAILED DESCRIPTION

To better illustrate the present disclosure and facilitate understanding of technical solutions thereof, the present disclosure is further described in detail below. However, the following embodiments are merely simple examples of the present disclosure and do not represent or limit the protection scope of the present disclosure. The protection scope of the present disclosure shall be defined by the claims as appended.

The detailed description section of the present disclosure provides a charging method for a battery. The charging method includes the following steps of: (1) determining an average charging rate Cₐ, an initial charging rate C₁, and a termination charging rate C_{T} based on a charging duration T and a predetermined first mapping table, and determining a charging duration t for a single charging rate and a rate increment I based on a predetermined battery cycle count n; and (2) determining a charging combination scheme based on the initial charging rate C₁, the termination charging rate C_{T}, the charging duration t for the single charging rate, and the rate increment I.

In the present disclosure, the rate increment I refers to a difference between two adjacent charging rates.

In the present disclosure,

$${\sum }_{n = 1}^{T} {tC}_{n} = 1 ,$$

where a unit of t in the formula is hour.

A specific mapping relationship exists between the initial charging rate and the predetermined charging duration. For the predetermined charging duration not included in the first mapping table, a corresponding initial rate for a charging duration close to the predetermined charging duration may be selected from the first mapping table as an initial rate for the predetermined charging duration.

In the present disclosure, the battery may be a lithium metal battery system. In the lithium metal battery system, an anode is a metal lithium or a lithium alloy. The lithium alloy includes, but is not limited to, Li-M, in which element M includes any one of or a combination of at least two of Zn, C, Ag, Al, K, Mg, Pb, Si, Sn, Ge, Sb, or Bi.

The present disclosure imposes no limitation on a lithium metal battery and a method for preparing same. Known industrial cell preparation methods may be adopted. For example, the lithium metal battery can be prepared through stacking or winding an anode, a separator, and a cathode sequentially to form a cell, and placing the cell in an aluminum-laminated film for packaging, electrolyte injection, formation, and secondary sealing.

As a preferred solution of the present disclosure, in the step (1), the average charging rate Cₐ=1/T.

As a preferred solution of the present disclosure, the charging duration satisfies 0.2 h≤T≤5 h, e.g., 0.2 h, 0.5 h, 1 h, 2 h, 3 h, 4 h, or 5 h. However, the present disclosure is not limited to any of the listed values. Other unlisted values within this numerical range are equally applicable.

As a preferred solution of the present disclosure, the predetermined first mapping table in the step (1) is configured to record an empirical correspondence between the predetermined charging duration and the initial charging rate.

As a preferred solution of the present disclosure, the termination charging rate C_{T} in the step (1) is calculated based on a formula C_{T}=2Cₐ−C₁.

As a preferred solution of the present disclosure, in the step (1), the charging duration for the single charging rate satisfies

$$t = \frac{T}{2 n + β} ,$$

and the rate increment satisfies

$$I = \frac{{C}_{T} - {C}_{1}}{2 n + β} ,$$

where β represents a correction factor, 100≤β≤1000, and β is an integer, e.g., 100, 200, 300, 400, 500, 600, 700, 800, 900, or 1000. However, the present disclosure is not limited to any of the listed values. Other unlisted values within this numerical range are equally applicable. β=0 during first charging. In the present disclosure, since the correction factor is not introduced during the first charging, β=0 during the first charging.

As a preferred solution of the present disclosure, in the step (1), n≥100, e.g., 100, 200, 300, 400, 500, 600, 700, 800, 900, or 1000. However, the present disclosure is not limited to any of the listed values. Other unlisted values within this numerical range are equally applicable.

As a preferred solution of the present disclosure, the charging combination scheme in the step (2) includes a combination of (2n+β+1) charging rates. The single charging rate corresponds to the charging duration t.

As a preferred solution of the present disclosure, the charging combination scheme in the step (2) includes: charging at the initial charging rate C₁, and charging sequentially at remaining (2n+β) charging rates in an ascending order of magnitude of the remaining (2n+β) charging rates, where β represents a correction factor, 100≤β≤1000 and β is an integer, e.g., 100, 200, 300, 400, 500, 600, 700, 800, 900, or 1000. However, the present disclosure is not limited to any of the listed values. Other unlisted values within this numerical range are equally applicable. β=0 during first charging.

As a preferred solution of the present disclosure, the charging combination scheme in the step (2) includes: charging at the initial charging rate C₁ for t hours when an SOC of the battery is 0%, switching to charge at a rate of C₁+k*I for t hours, repeating the switching sequentially until (2n+β) switches have been performed, and ending with charging at the termination charging rate C_{T} for t hours, where k represents a quantity of switches.

As a preferred solution of the present disclosure, during charging at the single charging rate in the step (2), charging cut-off voltage protection is set.

As a preferred solution of the present disclosure, a cut-off condition for the charging cut-off voltage protection is: ending a charging process at a current rate, and switching to charging at a next rate, when a charging voltage of the battery reaches 4.3V.

As a preferred solution of the present disclosure, the charging method further includes the following step of: (3) verifying the charging combination scheme, correcting the charging combination scheme when a correction of the charging combination scheme is required subsequent to the verifying the charging combination scheme, and continuing the verifying subsequent to the correcting, until the charging combination scheme meets an evaluation criterion.

In the present disclosure, for the lithium metal battery, the verifying refers to performing a charge-discharge cycle verification using the lithium metal battery.

As a preferred solution of the present disclosure, in the step (3), the verifying includes: performing a cycle test on the battery based on the charging combination scheme, measuring an actual cycle count nᵣ at which a capacity retention rate of the battery declines to 80%, and verifying the charging combination scheme based on a difference between the predetermined battery cycle count n and the actual cycle count nᵣ.

As a preferred solution of the present disclosure, when n−nᵣ≤25 (e.g., 25, 23, 20, 17, 15, 13, 10, or −5, but the present disclosure is not limited to any of the listed values; other unlisted values within this numerical range are equally applicable), the charging combination scheme meets a predetermined requirement.

When 25<n−nᵣ≤50 (e.g., 27, 30, 35, 40, 45, or 50, but the present disclosure is not limited to any of the listed values; other unlisted values within this numerical range are equally applicable), a correction is required for each of the charging duration t for the single charging rate and the rate increment I.

When 50<n−nᵣ (e.g., 53, 55, 60, 65, 70, 75, 80, or 85, but the present disclosure is not limited to any of the listed values; other unlisted values within this numerical range are equally applicable), a correction is required for the initial charging rate C₁.

As a preferred solution of the present disclosure, when 25<n−nᵣ≤50, a correction factor β is introduced to correct the charging duration t for the single charging rate and the rate increment I, where

$$t = \frac{T}{2 n + β} ,$$

the rate increment satisfies

$$I = \frac{{C}_{T} - {C}_{1}}{2 n + β} ,$$

100≤β≤1000 and β is an integer, and a value of β increases as a quantity of corrections increases.

In the present disclosure, the value of β is determined with reference to a magnitude of (n−nᵣ). The value of β increases as the magnitude of (n−nᵣ) increases, primarily based on empirical value determination.

In the present disclosure, selecting an appropriate correction factor β alone can satisfy a predetermined charging condition. Within a value range of β, any combined charging method formed under a condition where a selected value is greater than or equal to β can satisfy the predetermined charging condition.

As a preferred solution of the present disclosure, when 50<n−nᵣ, a correction factor α is introduced to correct the initial charging rate C₁, the termination charging rate C_{T}, and the rate increment I, where 0.5≤α<1, and a new initial rate C₁₊ₘ=α*C₁, where m represents a quantity of corrections, and a value of a decreases as the quantity of corrections increases.

In the present disclosure, the value of a is determined with reference to a magnitude of (n−nᵣ). The value of a decreases as the magnitude of (n−nᵣ) increases, primarily based on empirical value determination.

In the present disclosure, selecting an appropriate correction factor α alone can satisfy the predetermined charging condition. Within a value range of a, any combined charging method formed under a condition where a selected value is smaller than or equal to a can satisfy the predetermined charging condition.

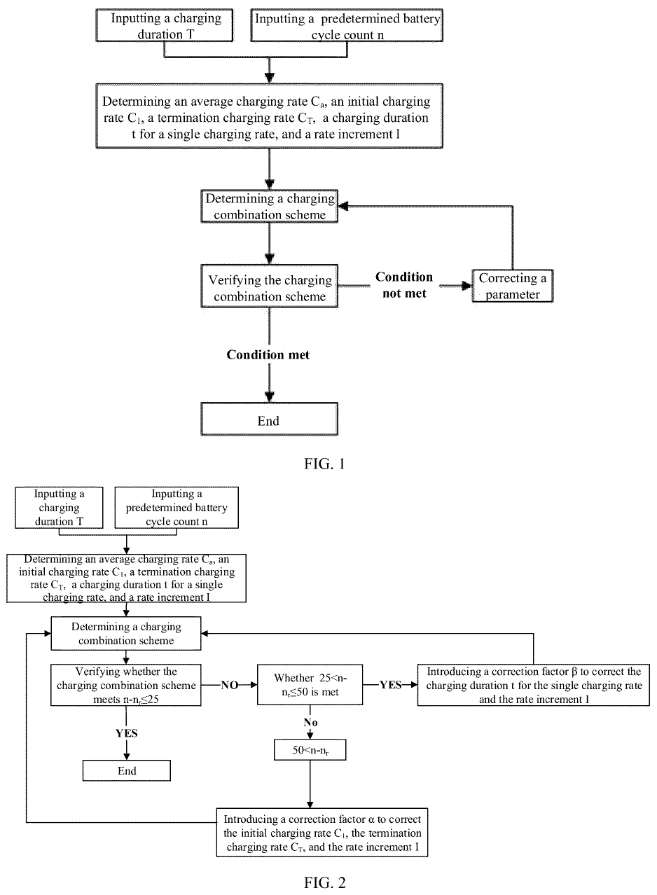

More specifically, as illustrated in FIG. 1, the charging method of the present disclosure includes: (1) determining the average charging rate Cₐ, the initial charging rate C₁, and the termination charging rate C_{T} based on the charging duration T and the predetermined first mapping table, and determining the charging duration t for the single charging rate and the rate increment I based on the predetermined battery cycle count n; (2) determining the charging combination scheme based on the initial charging rate C₁, the termination charging rate C_{T}, the charging duration t for the single charging rate, and the rate increment I; and (3) verifying the charging combination scheme: completing charging when the charging combination scheme meets a requirement subsequent to the verifying; and correcting the charging combination scheme when the charging combination scheme fails to meet a charging requirement subsequent to the verifying, and continuing the verifying subsequent to the correcting, until the charging combination scheme meets the evaluation criterion.

Further, as illustrated in FIG. 2, the charging method of the present disclosure includes: (1) determining the average charging rate Cₐ, the initial charging rate C₁, and the termination charging rate C_{T} based on the charging duration T and the predetermined first mapping table, where Cₐ=1/T, 0.2 h≤T≤5 h, C₁ is determined based on the predetermined first mapping table, and C_{T}=2Cₐ−C₁; and determining the charging duration t for the single charging rate and the rate increment I based on the predetermined battery cycle count n, in which the charging duration for the single charging rate satisfies

$$t = \frac{T}{2 n + β} ,$$

and the rate increment satisfies

$$I = \frac{{C}_{T} - {C}_{1}}{2 n + β} ,$$

where β represents the correction factor, 100≤β≤1000 and β is an integer, β=0 during the first charging, and n≥100; (2) determining the charging combination scheme based on the initial charging rate C₁, the termination charging rate C_{T}, the charging duration t for the single charging rate, and the rate increment I, in which the charging combination scheme includes: charging at the initial charging rate C₁, and charging sequentially at the remaining (2n+β) charging rates in the ascending order of magnitude of the remaining (2n+β) charging rates, where β represents the correction factor, 100≤β≤1000 and β is an integer, and β=0 during the first charging; and (3) verifying the charging combination scheme: completing charging when the charging combination scheme meets the requirement subsequent to the verifying; and correcting the charging combination scheme when the charging combination scheme fails to meet the charging requirement subsequent to the verifying, and continuing the verifying subsequent to the correcting, until the charging combination scheme meets the evaluation criterion. The verifying includes: performing the cycle test on the battery based on the charging combination scheme, measuring the actual cycle count nᵣ at which the capacity retention rate of the battery declines to 80%, and verifying the charging combination scheme based on the difference between the predetermined battery cycle count n and the actual cycle count nᵣ. When n−nᵣ≤25, the charging combination scheme meets the predetermined requirement. When 25<n−nᵣ≤50, the correction factor β is introduced to correct the charging duration t for the single charging rate and the rate increment I, where

$$t = \frac{T}{2 n + β} ,$$

the rate increment satisfies

$$I = \frac{{C}_{T} - {C}_{1}}{2 n + β} ,$$

100≤β≤1000 and β is an integer, and the value of β increases as the quantity of corrections increases. When 50<n−nᵣ, the correction factor α is introduced to correct the initial charging rate C₁, the termination charging rate C_{T}, and the rate increment I, where 0.5≤α<1, and the new initial rate C₁₊ₘ=α*C₁, where m represents the quantity of corrections, and the value of a decreases as the quantity of corrections increases.

The detailed description section of the present disclosure further provides a charging device. The charging device includes: a charging duration input module configured to allow for an input of a charging duration T that is predetermined; a charging rate obtaining module configured to determine an average charging rate Cₐ, an initial charging rate C₁, and a termination charging rate C_{T} based on the charging duration T and a predetermined first mapping table; a cycle count input module configured to allow for an input of a predetermined battery cycle count n; a single-charging-rate charging duration and rate increment obtaining module configured to determine a charging duration t for a single charging rate and a rate increment I based on the predetermined battery cycle count n, the charging duration T, the initial charging rate C₁, and the termination charging rate C_{T}; a charging combination scheme determination module configured to generate a charging combination scheme; and a charging module configured to charge a battery based on the charging combination scheme.

As a preferred solution of the present disclosure, the charging device further includes: a verification and determination module configured to verify a charging result, for determining whether a correction is required for the charging combination scheme; and a correction module configured to correct the charging combination scheme based on a verification and determination result.

As a preferred solution of the present disclosure, the correction module includes: a correction factor α input module configured to allow for an input of a value of α; an initial charging rate C₁, termination charging rate C_{T}, and rate increment I correction module configured to correct the initial charging rate C₁, the termination charging rate C_{T}, and the rate increment I based on the input correction factor α; a correction factor β input module configured to allow for an input of a value of β; a single-charging-rate charging duration t and rate increment I correction module configured to correct the charging duration t for the single charging rate and the rate increment I based on the input correction factor; and an output module configured to output the corrected charging combination scheme that meets predetermined performance.

In the present disclosure, subsequent to the output module outputting the corrected charging combination scheme and the charging module performing charging, a verification continues through the verification and determination module, until the charging combination scheme meets the evaluation criterion.

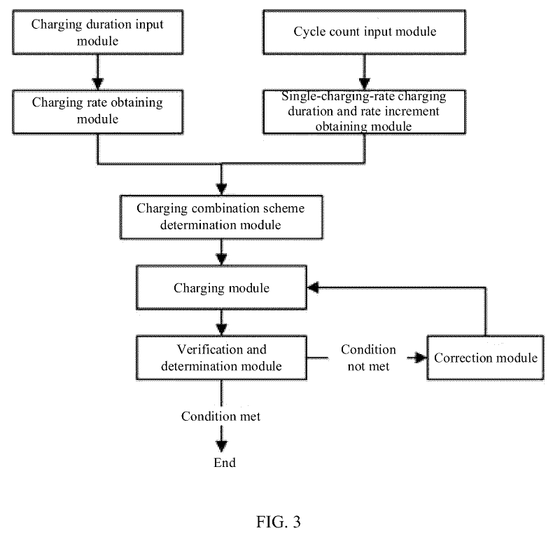

More specifically, as illustrated in FIG. 3, the charging device of the present disclosure includes: a charging duration input module configured to allow for an input of a charging duration T that is predetermined; a charging rate obtaining module configured to determine an average charging rate Cₐ, an initial charging rate C₁, and a termination charging rate C_{T} based on the charging duration T and a predetermined first mapping table; a cycle count input module configured to allow for an input of a predetermined battery cycle count n; a single-charging-rate charging duration and rate increment obtaining module configured to determine a charging duration t for a single charging rate and a rate increment I based on the predetermined battery cycle count n, the charging duration T, the initial charging rate C₁, and the termination charging rate C_{T}; a charging combination scheme determination module configured to generate a charging combination scheme; a charging module configured to charge a battery based on the charging combination scheme; a verification and determination module configured to verify a charging result, for determining whether a correction is required for the charging combination scheme; and a correction module configured to correct the charging combination scheme based on a verification and determination result.

The following are typical but non-limiting examples of the present disclosure.

### Example 1

This example provides a method for preparing a lithium metal battery. The method includes the following steps.
(1) Preparation of a cathode sheet: a cathode active material LiNi_{0.8}Co_{0.1}Mn_{0.1}O₂, a binder polyvinylidene fluoride, and a conductive agent carbon black are dissolved in an N-methyl-2-pyrrolidone solution at a mass ratio of 98:1:1 to prepare a slurry having a solid content of 70%. The slurry is coated on a surface of an aluminum foil, dried by baking at 85° C., and then cold-pressed and cut (86 mm*66 mm) to obtain the cathode sheet.
(2) Preparation of an anode sheet: a lithium-copper composite strip (a 10 μm copper foil coated on both sides with 50 μm lithium foil) is cut into an anode sheet of a dimension of 88 mm*68 mm.
(3) Preparation of an electrolyte: in a dry argon atmosphere, a mixed solution of 1 M lithium hexafluorophosphate in ethylene carbonate (EC)/ethyl methyl carbonate (EMC) is prepared. A mass ratio of EC to EMC in the mixed solution is 1:1.
(4) Preparation of the lithium metal battery: a polyethylene separator having a thickness of 20 μm is selected. An anode, the separator, and a cathode are stacked sequentially. The stacked cell structure is fixed with an adhesive tape and placed in an aluminum-laminated film. Top and side sealing, electrolyte injection, packaging, formation, and secondary sealing are performed to obtain the lithium metal battery.

The following Example 2 to Example 5 and Comparative Example 1 to Comparative Example 4 all employ the lithium metal battery prepared in Example 1 for charging and verification. Since the charging duration at a single rate shown in these examples is relatively short, the charging duration t at the single rate is expressed in seconds for ease of presentation.

### Example 2

This example provides a combined charging method for a lithium metal battery. The combined charging method includes the following steps.

(1) The charging duration for the lithium metal battery is predetermined as T=2.5 h, and a cycle count at a discharge rate of 1 C is predetermined as n=400. The average charging rate Cₐ=0.4 is obtained based on the predetermined charging duration T. Based on the average charging rate Cₐ−0.4 and the first mapping table (Table 1), the initial charging rate C₁=0.1 is obtained. The termination rate C_{T}=0.7 is calculated using the formula C_{T}=2Cₐ−C₁. Based on the predetermined cycle count n,

$$t = \frac{T}{2 n + β} , and I = \frac{{C}_{T} - {C}_{1}}{2 n + β} ,$$

the charging duration t for the single rate is obtained as t=11.25 s (without the correction; β is initially set to 0), and the increment I between adjacent rates is obtained as I=0.00075.

(2) The combined charging method is formed based on the initial rate Cₐ, the termination rate C_{T}, the charging duration t for the single rate, and the increment I between adjacent rates. Specific steps of the combined charging method are as follows. Starting from SOC=0%, the lithium metal battery is charged at a constant current at a rate of C₁=0.1 for the charging duration of t=11.25 s. Immediately in response to a completion of this stage, the charging rate switches to C₁+k*I (k=1, and I=0.00075) for constant-current charging with the charging duration of t=11.25 s. This process continues analogously, until (2n+β) switches (n=400, with no correction introduced initially, and β=0) have been performed, in which case the lithium metal battery is charged at a constant current with the rate C_{T}=0.7 for the charging duration of t=11.25 s. To enhance charging safety of the lithium metal battery, a charging voltage protection process is implemented during charging at each single rate. Specifically: during charging at any single rate, when a charging voltage of the lithium metal battery exceeds 4.3 V, a current charging process is terminated immediately, and the charging process proceeds directly to a next rate.

(3) A cycle test of the above combined charging method is performed on the lithium metal battery, with the discharge rate consistent with the predetermined discharge rate. The cycle count achieved by the current combined charging method is obtained as nᵣ=394. By evaluating n−nᵣ, the criterion of n−nᵣ≤25 is met. Therefore, the combined charging method obtained above is deemed suitable for meeting charging performance requirements of the current lithium metal battery.

TABLE 1
First mapping table
Initial SOC = 0%

| | | | | | | | | | | | | | | |
|---|---|---|---|---|---|---|---|---|---|---|---|---|---|---|
| Predetermined | 2.5 | 1.67 | 1.25 | 1 | 0.833 | 0.714 | 0.625 | 0.556 | 0.5 | 0.455 | 0.417 | 0.384 | 0.357 | 0.333 |
| charging duration | | | | | | | | | | | | | | |
| (h) | | | | | | | | | | | | | | |
| Average charging | 0.4 | 0.6 | 0.8 | 1 | 1.2 | 1.4 | 1.6 | 1.8 | 2 | 2.2 | 2.4 | 2.6 | 2.8 | 3 |
| rate Cₐ | | | | | | | | | | | | | | |
| Initial charging | 0.1 | 0.2 | 0.3 | 0.4 | 0.55 | 0.7 | 0.85 | 1 | 1.15 | 1.3 | 1.5 | 1.7 | 1.9 | 2.1 |
| rate C₁ | | | | | | | | | | | | | | |

### Example 3

This example provides a combined charging method for a lithium metal battery. The combined charging method includes the following steps.

(1) The charging duration for the lithium metal battery is predetermined as T=1.25 h, and the cycle count at the discharge rate of 1 C is predetermined as n=300. The average charging rate Cₐ=0.8 is obtained based on the predetermined charging duration T. Based on the average charging rate Cₐ−0.8 and the first mapping table (Table 1), the initial charging rate C₁=0.3 is obtained. The termination rate C_{T}=1.3 is calculated using the formula C_{T}=2Cₐ−C₁. Based on the predetermined cycle count n,

$$t = \frac{T}{2 n + β} , and I = \frac{{C}_{T} - {C}_{1}}{2 n + β} ,$$

the charging duration t for the single rate is obtained as t=7.5 s (without the correction; β is initially set to 0), and the increment I between adjacent rates is obtained as I=0.00167.

(2) The combined charging method is formed based on the initial rate Cₐ, the termination rate C_{T}, the charging duration t for the single rate, and the increment I between adjacent rates. Specific steps of the combined charging method are as follows. Starting from SOC=0%, the lithium metal battery is charged at a constant current at a rate of C₁=0.3 for the charging duration of t=7.5 s. Immediately in response to a completion of this stage, the charging rate switches to C₁+k*I (k=1, and I=0.00167) for constant-current charging with the charging duration of t=7.5 s. This process continues analogously, until (2n+β) switches (n=300, with no correction introduced initially, and β=0) have been performed, in which case the lithium metal battery is charged at a constant current with the rate C_{T}=1.3 for the charging duration of t=7.5 s. To enhance the charging safety of the lithium metal battery, the charging voltage protection process is implemented during charging at each single rate. Specifically: during charging at any single rate, when the charging voltage of the lithium metal battery exceeds 4.3 V, a current charging process is terminated immediately, and the charging process proceeds directly to a next rate.

(3) A cycle test of the above combined charging method is performed on the lithium metal battery, with the discharge rate consistent with the predetermined discharge rate. The cycle count achieved by the current combined charging method is obtained as nᵣ=273. By evaluating n−nᵣ, the criterion of n−nᵣ≤25 is not met. Therefore, the above combined charging method requires a correction. Since 25<n−nᵣ≤50, the correction factor β needs to be introduced to correct the charging duration t for the single rate and the increment I between adjacent rates. For a 1-st time of correction, β is set to 100. Based on the formulas

$$t = \frac{T}{2 n + β} and I = \frac{{C}_{T} - {C}_{1}}{2 n + β} ,$$

t=6.43 s and I=0.00143 are calculated. Based on the corrected charging duration t for the single rate and the corrected increment I between adjacent rates, the corrected combined charging method is obtained. A cycle test of the above corrected combined charging method is performed on the lithium metal battery, with the discharge rate consistent with the predetermined discharge rate. The cycle count achieved by the current corrected combined charging method is obtained as nᵣ=286. By evaluating n−nᵣ, the criterion of n−nᵣ≤25 is met. Therefore, the corrected combined charging method obtained above is deemed suitable for meeting the charging performance requirements of the current lithium metal battery.

### Example 4

This example provides a combined charging method for a lithium metal battery. The combined charging method includes the following steps.

(1) The charging duration for the lithium metal battery is predetermined as T=1 h, and the cycle count at the discharge rate of 1 C is predetermined as n=250. The average charging rate Cₐ=1 is obtained based on the predetermined charging duration. Based on the average charging rate Cₐ=1 and the first mapping table (Table 1), the initial charging rate C₁=0.4 is obtained. The termination rate C_{T}=1.6 is calculated using the formula C_{T}=2Cₐ−C₁. Based on the predetermined cycle count n,

$$t = \frac{T}{2 n + β} , and I = \frac{{C}_{T} - {C}_{1}}{2 n + β} ,$$

the charging duration t for the single rate is obtained as t=7.2 s (without the correction; β is initially set to 0), and the increment I between adjacent rates is obtained as I=0.0024.

(2) The combined charging method is formed based on the initial rate Cₐ, the termination rate C_{T}, the charging duration t for the single rate, and the increment I between adjacent rates. Specific steps of the combined charging method are as follows. Starting from SOC=0%, the lithium metal battery is charged at a constant current at a rate of C₁=0.4 for the charging duration of t=7.2 s. Immediately in response to a completion of this stage, the charging rate switches to C₁+k*I (k=1, and I=0.0024) for constant-current charging with the charging duration of t=7.2 s. This process continues analogously, until (2n+β) switches (n=250, with no correction introduced initially, and β=0) have been performed, in which case the lithium metal battery is charged at a constant current with the rate C_{T}=1.6 for the charging duration of t=7.2 s. To enhance the charging safety of the lithium metal battery, the charging voltage protection process is implemented during charging at each single rate. Specifically: during charging at any single rate, when the charging voltage of the lithium metal battery exceeded 4.3 V, a current charging process is terminated immediately, and the charging process proceeds directly to a next rate.

(3) A cycle test of the above combined charging method is performed on the lithium metal battery, with the discharge rate consistent with the predetermined discharge rate. The cycle count achieved by the current combined charging method is obtained as nᵣ=203. By evaluating n−nᵣ, the criterion of n−nᵣ≤25 is not met. Therefore, the above combined charging method requires a correction. Since 25<n−nᵣ≤50, the correction factor β needs to be introduced to correct the charging duration t for the single rate and the increment I between adjacent rates. For a 1-st time of correction, β is set to 100. Based on the formulas

$$t = \frac{T}{2 n + β} and I = \frac{{C}_{T} - {C}_{1}}{2 n + β} ,$$

t=6 s and I=0.002 are calculated. Based on the corrected charging duration t for the single rate and the corrected increment I between adjacent rates, the corrected combined charging method is obtained. A cycle test of the above corrected combined charging method is performed on the lithium metal battery, with the discharge rate consistent with the predetermined discharge rate. The cycle count achieved by the current corrected combined charging method is obtained as nᵣ=223. By evaluating n−nᵣ, the criterion of n−nᵣ≤25 is still not met. Therefore, the above combined charging method requires a further correction. Since nᵣ=223 still shows a significant gap from the predetermined discharge rate cycle count n, a value of the correction factor β could be appropriately increased, for example, setting β to 300. Based on the formulas

$$t = \frac{T}{2 n + β} and I = \frac{{C}_{T} - {C}_{1}}{2 n + β} ,$$

t=4.5 s and I=0.0015 are calculated. Based on the further corrected charging duration t for the single rate and the further corrected increment I between adjacent rates, the further corrected combined charging method is obtained. A cycle test of the above further corrected combined charging method is performed on the lithium metal battery, with the discharge rate consistent with the predetermined discharge rate. The cycle count achieved by the current further corrected combined charging method is obtained as nᵣ=237. By evaluating n−nᵣ, the criterion of n−nᵣ≤25 is met. Therefore, the further corrected combined charging method obtained above is deemed suitable for meeting the charging performance requirements of the current lithium metal battery.

### Example 5

This example provides a combined charging method for a lithium metal battery. The combined charging method includes the following steps.

(1) The charging duration for the lithium metal battery is predetermined as T=0.715 h, and the cycle count at the discharge rate of 1 C is predetermined as n=200. The average charging rate Cₐ−1.4 is obtained based on the predetermined charging duration. Based on the average charging rate Cₐ=1.4 and the first mapping table (Table 1), the initial charging rate C₁=0.7 is obtained. The termination rate C_{T}=2.1 is calculated using the formula C_{T}=2Cₐ−C₁. Based on the predetermined cycle count n,

$$t = \frac{T}{2 n + β} , and I = \frac{{C}_{T} - {C}_{1}}{2 n + β} ,$$

the charging duration t for the single rate is obtained as t=6.435 s (without the correction; β is initially set to 0), and the increment I between adjacent rates is obtained as I=0.0035.

(2) The combined charging method is formed based on the initial rate Cₐ, the termination rate C_{T}, the charging duration t for the single rate, and the increment I between adjacent rates. Specific steps of the combined charging method are as follows. Starting from SOC=0%, the lithium metal battery is charged at a constant current at a rate of C₁=0.7 for the charging duration of t=6.435 s. Immediately in response to a completion of this stage, the charging rate switches to C₁+k*I (k=1, and I=0.0035) for constant-current charging with the charging duration of t=6.435 s. This process continues analogously, until (2n+β) switches (n=250, with no correction introduced initially, and β=0) have been performed, in which case the lithium metal battery is charged at a constant current with the rate C_{T}=2.1 for the charging duration of t=6.435 s. To enhance the charging safety of the lithium metal battery, the charging voltage protection process is implemented during charging at each single rate. Specifically: during charging at any single rate, when the charging voltage of the lithium metal battery exceeds 4.3 V, a current charging process is terminated immediately, and the charging process proceeds directly to a next rate.

(3) A cycle test of the above combined charging method is performed on the lithium metal battery, with the discharge rate consistent with the predetermined discharge rate. The cycle count achieved by the current combined charging method is obtained as nᵣ=123. By evaluating n−nᵣ, the criterion of n−nᵣ≤25 is not met. Therefore, the above combined charging method requires a correction. Since 50<n−nᵣ, the correction factor α needs to be introduced to correct the initial charging rate C₁, the termination rate Cr, and the rate increment I. Given that an actual cycle count of the above combined charging method deviates significantly from the predetermined discharge rate cycle count, a relatively small value is selected from the range of α. For a 1-st time of selection, α=0.8 is chosen, yielding the corrected initial charging rate C₁=0.56, the corrected termination rate C_{T}=2.24, and the corrected increment I=0.0042. Based on the corrected initial charging rate C₁, the corrected termination rate C_{T}, and the corrected increment I, the corrected combined charging method is obtained. Verification of the above charging method is performed on the lithium metal battery. The cycle count achieved with the current corrected combined charging method is obtained as nᵣ=157. By evaluating n−nᵣ, the criterion of n−nᵣ≤25 is still not met. Therefore, the above combined charging method requires a further correction. Since 25≤n=nᵣ<50, the charging duration t for the single rate and the increment I between adjacent rates needs to be corrected. Given that the actual cycle count of the above combined charging method deviates significantly from the predetermined discharge rate cycle count, a relatively large value is selected from the range of β. For the further correction, β is set to 400. Based on the formulas

$$t = \frac{T}{2 n + β} and I = \frac{{C}_{T} - {C}_{1}}{2 n + β} ,$$

t=3.22 s and I=0.0021 are calculated. Based on the corrected charging duration t for the single rate and the corrected increment I between adjacent rates, the further corrected combined charging method is obtained. A cycle test of the above further corrected combined charging method is performed on the lithium metal battery, with the discharge rate consistent with the predetermined discharge rate. The cycle count achieved by the current further corrected combined charging method is obtained as nᵣ=179. By evaluating n−nᵣ, the criterion of n−nᵣ≤25 is met. Therefore, the further corrected combined charging method obtained above is deemed suitable for meeting the charging performance requirements of the current lithium metal battery.

### Comparative Example 1

This comparative example provides a charging method for a lithium metal battery. The predetermined charging duration and cycling performance at a specific discharge rate in Comparative Example 1 is consistent with those in Example 2. The charging method is conventional constant-rate charging, specifically charging at the rate of Cₐ=0.4 for the charging duration of T=2.5 h. Further, to enhance the charging safety of the lithium metal battery, the charging voltage protection process is implemented during charging at this rate. Specifically: during charging at the rate of Cₐ−0.4, when the charging voltage of the lithium metal battery exceeds 4.3 V, charging is terminated immediately, and the process switches to the discharge process. A cycle test of the above charging method is performed on the lithium metal battery, with the discharge rate consistent with the predetermined discharge rate. The cycle count achieved by the current combined charging method is obtained as nᵣ=198.

### Comparative Example 2

This comparative example provides a charging method for a lithium metal battery. The predetermined charging duration and cycling performance at a specific discharge rate in Comparative Example 2 are consistent with those in Example 3. The charging method is conventional constant-rate charging, specifically charging at the rate of Cₐ=0.8 for the charging duration of T=1.25 h. Further, to enhance the charging safety of the lithium metal battery, the charging voltage protection process is implemented during charging at this rate. Specifically: during charging at the rate of Cₐ=0.8, when the charging voltage of the lithium metal battery exceeds 4.3 V, charging is terminated immediately, and the process switches to the discharge process. A cycle test of the above charging method is performed on the lithium metal battery, with the discharge rate consistent with the predetermined discharge rate. The cycle count achieved by the current combined charging method is obtained as nᵣ=146.

### Comparative Example 3

This comparative example provides a charging method for a lithium metal battery. The predetermined charging duration and cycling performance at a specific discharge rate in Comparative Example 3 are consistent with those in Example 4. The charging method is conventional constant-rate charging, specifically charging at the rate of Cₐ=1 for the charging duration of T=1 h. Further, to enhance the charging safety of the lithium metal battery, the charging voltage protection process is implemented during charging at this rate. Specifically: during charging at the rate of Cₐ=1, when the charging voltage of the lithium metal battery exceeded 4.3 V, charging is terminated immediately, and the process switches to the discharge process. A cycle test of the above charging method is performed on the lithium metal battery, with the discharge rate consistent with the predetermined discharge rate. The cycle count achieved by the current combined charging method is obtained as nᵣ=89.

### Comparative Example 4

This comparative example provides a charging method for a lithium metal battery. The predetermined charging duration and cycling performance at a specific discharge rate in Comparative Example 4 are consistent with those in Example 5. The charging method is conventional constant-rate charging, specifically charging at the rate of Cₐ=1.4 for the charging duration of T=0.715 h. Further, to enhance the charging safety of the lithium metal battery, the charging voltage protection process is implemented during charging at this rate. Specifically: during charging at the rate of Cₐ−1.4, when the charging voltage of the lithium metal battery exceeds 4.3 V, charging is terminated immediately, and the process switches to the discharge process. A cycle test of the above charging method is performed on the lithium metal battery, with the discharge rate consistent with the predetermined discharge rate. The cycle count achieved by the current combined charging method is obtained as nᵣ=46.

Test results of the cycling performance of the lithium metal batteries in Example 2 to Example 5 and Comparative Example 1 to Comparative Example 4 are shown in Table 2.

TABLE 2
Test Results of Example 2 to Example 5 and Comparative
Example 1 to Comparative Example 4

| Charging duration (h) | 2.5 | 1.25 | 1 | 0.715 |
|---|---|---|---|---|
| Example | Example 2 | Example 3 | Example 4 | Example 5 |
| Cycling performance of | 394 | 286 | 237 | 179 |
| Examples | | | | |
| Comparative Example | Comparative | Comparative | Comparative | Comparative |
| | Example 1 | Example 2 | Example 3 | Example 4 |
| Cycling performance of | 198 | 146 | 89 | 46 |
| Comparative Examples | | | | |

Table 2 reveals that, by introducing the combined charging method, satisfactory cycling performance of the lithium metal battery can be maintained under relatively high-rate charging conditions. Compared with conventional constant-current charging, the cycle count of the lithium metal battery is significantly increased.

In an embodiment, a charging apparatus is provided. The charging apparatus includes a processor and a memory. The memory stores a program or an instruction executable in the processor. The program or the instruction, when executed by the processor, implements the steps of the charging method for the battery according to the present disclosure.

It should be noted that, the steps of the charging method for the battery according to the present disclosure may be specifically achieved in any computer-readable medium to be used by an instruction execution system, apparatus or device (such as a system based on computers, a system including a processing module, or other systems capable of obtaining instructions from the instruction execution system, apparatus and device and executing the instructions), or to be used in combination with the instruction execution system, apparatus and device. As to the specification, “the computer-readable storage medium” may be any apparatus adaptive for including, storing, communicating, propagating or transferring programs to be used by or in combination with the instruction execution system, apparatus or device. More specific examples of the computer-readable medium comprise but are not limited to: an electronic connection (an electronic apparatus) with one or more wires, a portable computer enclosure (a magnetic apparatus), a random access memory (RAM), a read only memory (ROM), an erasable programmable read-only memory (EPROM or a flash memory), an optical fiber apparatus, and a portable compact disk read-only memory (CDROM). In addition, the computer-readable medium may even be a paper or other appropriate medium capable of printing programs thereon, this is because, for example, the paper or other appropriate medium may be optically scanned and then edited, decrypted or processed with other appropriate methods when necessary to obtain the programs in an electric manner, and then the programs may be stored in the computer memories.

It is declared that the detailed process equipment and procedures of the present disclosure are described through the above embodiments. However, the present disclosure is not limited to the above detailed process equipment and procedures, meaning that the implementation of the present disclosure does not necessarily depend on the above detailed process equipment and procedures. Those skilled in the art should understand that, any improvements to the present disclosure, equivalent substitutions of the raw materials for the products of the present disclosure, additions of auxiliary components, choices of specific methods, etc., all fall within the protection scope and disclosure of the present disclosure.

What is claimed is:

1. A charging method for a battery, the charging method comprising the following steps of:
(1) determining an average charging rate Cₐ, an initial charging rate C₁, and a termination charging rate C_{T} based on a charging duration T and a predetermined first mapping table, and determining a charging duration t for a single charging rate and a rate increment I based on a predetermined battery cycle count n; and
(2) determining a charging combination scheme based on the initial charging rate C₁, the termination charging rate C_{T}, the charging duration t for the single charging rate, and the rate increment I.

2. The charging method according to claim 1, wherein in the step (1), the average charging rate Cₐ=1/T.

3. The charging method according to claim 1, wherein the charging duration satisfies 0.2 h≤T≤5 h.

4. The charging method according to claim 1, wherein the predetermined first mapping table in the step (1) is configured to record an empirical correspondence between the predetermined charging duration T and the initial charging rate C₁.

5. The charging method according to claim 1, wherein the termination charging rate C_{T} in the step (1) is calculated based on a formula C_{T}=2Cₐ−C₁.

6. The charging method according to claim 1, wherein in the step (1), the charging duration for the single charging rate satisfies
$$t = \frac{T}{2 n + β} ,$$
and the rate increment satisfies
$$I = \frac{{C}_{T} - {C}_{1}}{2 n + β} ,$$
where β represents a correction factor, 100≤β≤1000 and β is an integer, and β=0 during first charging.

7. The charging method according to claim 1, wherein in the step (1), n≥100.

8. The charging method according to claim 1, wherein the charging combination scheme in the step (2) comprises a combination of (2n+β+1) charging rates, the single charging rate corresponding to the charging duration t.

9. The charging method according to claim 8, wherein the charging combination scheme in the step (2) comprises: charging at the initial charging rate C₁, and charging sequentially at remaining (2n+β) charging rates in an ascending order of magnitude of the remaining (2n+β) charging rates, where β represents a correction factor, 100≤β≤1000 and β is an integer, and β=0 during first charging.

10. The charging method according to claim 8, wherein the charging combination scheme in the step (2) comprises: charging at the initial charging rate C₁ for t hours when a state of charge of the battery is 0%, switching to charge at a rate of C₁+k*I for t hours, repeating the switching sequentially until (2n+β) switches have been performed, and ending with charging at the termination charging rate C_{T} for t hours, where k represents a quantity of switches.

11. The charging method according to claim 8, wherein during charging at the single charging rate in the step (2), charging cut-off voltage protection is set.

12. The charging method according to claim 11, wherein a cut-off condition for the charging cut-off voltage protection is: ending a charging process at a current rate, and switching to charging at a next rate, when a charging voltage of the battery reaches 4.3V.

13. The charging method according to claim 1, further comprising the following step of:
(3) verifying the charging combination scheme, correcting the charging combination scheme when a correction of the charging combination scheme is required subsequent to said verifying the charging combination scheme, and continuing said verifying subsequent to said correcting, until the charging combination scheme meets an evaluation criterion.

14. The charging method according to claim 13, wherein in the step (3), said verifying comprises: performing a cycle test on the battery based on the charging combination scheme, measuring an actual cycle count nᵣ at which a capacity retention rate of the battery declines to 80%, and verifying the charging combination scheme based on a difference between the predetermined battery cycle count n and the actual cycle count nᵣ, wherein:
when n−nᵣ≤25, the charging combination scheme meets a predetermined requirement;
when 25<n−nᵣ≤50, a correction is required for each of the charging duration t for the single charging rate and the rate increment I; and
when 50<n−nᵣ, a correction is required for the initial charging rate C₁.

15. The charging method according to claim 14, wherein when 25<n−nᵣ≤50, a correction factor β is introduced to correct the charging duration t for the single charging rate and the rate increment I, where
$$t = \frac{T}{2 n + β} ,$$
the rate increment satisfies
$$I = \frac{{C}_{T} - {C}_{1}}{2 n + β} ,$$
100≤β≤1000 and β is an integer, and a value of β increases as a quantity of corrections increases.

16. The charging method according to claim 14, wherein when 50<n−nᵣ, a correction factor α is introduced to correct the initial charging rate C₁, the termination charging rate C_{T}, and the rate increment I, where 0.5≤α<1, and a new initial rate C₁₊ₘ=α*C₁, where m represents a quantity of corrections, and a value of a decreases as the quantity of corrections increases.

17. A charging device, comprising:
a charging duration input module configured to allow for an input of a charging duration T that is predetermined;
a charging rate obtaining module configured to determine an average charging rate Cₐ, an initial charging rate C₁, and a termination charging rate C_{T} based on the charging duration T and a predetermined first mapping table;
a cycle count input module configured to allow for an input of a predetermined battery cycle count n;
a single-charging-rate charging duration and rate increment obtaining module configured to determine a charging duration t for a single charging rate and a rate increment I based on the predetermined battery cycle count n, the charging duration T, the initial charging rate C₁, and the termination charging rate C_{T};
a charging combination scheme determination module configured to generate a charging combination scheme; and
a charging module configured to charge a battery based on the charging combination scheme.

18. The charging device according to claim 17, further comprising:
a verification and determination module configured to verify a charging result, for determining whether a correction is required for the charging combination scheme; and
a correction module configured to correct the charging combination scheme based on a verification and determination result.

19. The charging device according to claim 18, wherein the correction module comprises:
a correction factor α input module configured to allow for an input of a value of α;
an initial charging rate C₁, termination charging rate C_{T}, and rate increment I correction module configured to correct the initial charging rate C₁, the termination charging rate C_{T}, and the rate increment I based on the input correction factor α;
a correction factor β input module configured to allow for an input of a value of β;
a single-charging-rate charging duration t and rate increment I correction module configured to correct the charging duration t for the single charging rate and the rate increment I based on the input correction factor β; and
an output module configured to output the corrected charging combination scheme that meets predetermined performance.

20. A non-transitory computer-readable storage medium having a computer program stored thereon, wherein the computer program, when executed by a processor, implements a charging method for a battery,
wherein the charging method comprises the following steps of:
(1) determining an average charging rate Cₐ, an initial charging rate C₁, and a termination charging rate C_{T} based on a charging duration T and a predetermined first mapping table, and determining a charging duration t for a single charging rate and a rate increment I based on a predetermined battery cycle count n; and
(2) determining a charging combination scheme based on the initial charging rate C₁, the termination charging rate C_{T}, the charging duration t for the single charging rate, and the rate increment I.
